(19) United States
(12) Patent Application Publication
(10) Pub. No.: US 2026/0330624 A1
(43) Pub. Date: Oct. 22, 2026

(54) Model Generating Method and Defect Inspection System

(71) Applicant: Hitachi High-Tech Corporation, Minato-ku, Tokyo (JP)

(72) Inventors: Taichi INADOMI, Tokyo (JP); Takahiro URANO, Tokyo (JP); Junji YAMAMOTO, Tokyo (JP); Nobuaki HIROSE, Tokyo (JP); Hisashi HATANO, Tokyo (JP); Hironori SAKURAI, Tokyo (JP)

(21) Appl. No.: 19/114,828

(22) PCT Filed: Sep. 26, 2022
(86) PCT No.: PCT/JP2022/035715

§ 371 Date: Mar. 25, 2025

(51) Int. Cl. G06T 7/00; G06N 3/0985; G06V 10/764

(52) U.S. Cl. CPC G06T 7/001; G06N 3/0985; G06V 10/764

(57) ABSTRACT

The present invention has: a first step for reading defect candidate images used for training deep learning models; a second step for assigning labels to a portion of the defect candidate images to create teaching images and evaluation images; a third step for, after updating the parameters for each of a plurality of the deep learning models using teaching images, evaluating the classification accuracy using the evaluation images, and selecting the best model with the highest classification accuracy among the plurality of deep learning models; and a fourth step for classifying defect candidate images that have not been assigned a label using the best model, and select a portion of the defect images for assigning labels on the basis of the DOI-likeness according to the best model, and executes the second step and the third step again after execution of the fourth step.

### TECHNICAL FIELD

The present invention relates to technology for classifying defect candidates into customer important defects (DOI) and false reports (Nuisance) using a deep learning model.

### BACKGROUND ART

Semiconductor devices are manufactured by performing a plurality of processes on wafers made of silicon or the like and forming fine circuits. In a manufacturing process of semiconductor devices, appearance inspection may be performed before and after each process in order to improve and stabilize yields. Among devices used for appearance inspection, a device used for appearance inspection of a wafer after a circuit pattern is formed detects pattern defects or defects such as foreign matter on the basis of a reference image and an inspection image obtained by irradiating a region corresponding to two patterns, which are formed to inherently have the same shape, with lamp light, laser light, electron beams, or the like. Specifically, a difference between the reference image and the inspection image is calculated, and parts with a difference larger than a separately determined threshold value are detected as defect candidates.

In such inspection, the lower the threshold value, the more minute the defects can be detected, but lowering the threshold value will result in a large number of false reports caused by errors or roughness when an image is acquired, minute differences in patterns, or differences in brightness due to uneven film thickness. Such false reports are referred to as Nuisance. On the other hand, defects desired to be detected by customers are referred to as defects of interest (DOI).

PTL 1 discloses that a threshold value for detecting defect candidates is set on the basis of variations in signals calculated for each region within a chip in order to eliminate false reports due to patterns. Examples of technology for removing Nuisance from defect candidates are also disclosed in PTL 2 and PTL 3.

### CITATION LIST

### Patent Literature

PTL 1: JP2000-105203A

PTL 2: JP2012-112915A

PTL 3: JP2014-149177A

### SUMMARY OF INVENTION

### Technical Problem

In the related art disclosed in PTL 2 and PTL 3, Nuisance included in defect candidates is analyzed and removal is achieved by designing a feature value for specifying Nuisance. For this reason, when Nuisance to be removed changes because the type of wafer to be inspected is changed or a process is changed, it is necessary to redesign the feature value.

Since work for several weeks to several months is required to design a feature value, it takes time to respond to changes in an object to be removed. On the other hand, it becomes easy to respond to changes in an object to be removed by applying a deep learning method to distinguish between DOI and Nuisance. This is because, when a deep learning method is applied, classification rules are automatically generated by teaching example images and training the deep learning model, and designing a feature value for specifying Nuisance is not necessary.

However, when defect candidate images are classified into DOI and Nuisance using deep learning, it is necessary to design an optimal deep learning model for each image type to be classified in order to enable classification with high accuracy. Here, the image type is a combination of an image of a background pattern and an image of a defect candidate. In addition, it is necessary to prepare approximately several thousands of labeled images for each class (here, DOI and Nuisance) as teaching data, and preparing the teaching data takes time and effort.

### Solution to Problem

A model generating method according to one embodiment of the present invention is a model generating method for generating a deep learning model for classifying defect candidate images into DOI and Nuisance, the model generating method including a first step of preparing a plurality of deep learning models with different hyper parameters in advance and reading defect candidate images to be used for training the deep learning models, a second step of labeling some of the defect candidate images to create teaching images and evaluation images, a third step of evaluating classification accuracy using the evaluation images after updating parameters for each of the plurality of deep learning models using the teaching images, and selecting a best model with the highest classification accuracy from among the plurality of deep learning models, and a fourth step of classifying the defect candidate images that have not been labeled using the best model, and selecting some of the defect candidate images to be labeled based on a DOI-likeness according to the best model, in which the second step and the third step are executed again after executing the fourth step.

### Advantageous Effects of Invention

According to the present invention, even when Nuisance to be removed changes, a deep learning model capable of removing Nuisance can be obtained in a short time, and thus it is possible to perform highly sensitive defect inspection at all times. Other problems and novel features will become apparent from the description of this specification and the accompanying drawings.

### BRIEF DESCRIPTION OF DRAWINGS

FIG. 1 is an example of a configuration of a defect inspection device.

FIG. 2A is an example of a hardware structure of an information processing device.

FIG. 2B is an example of a configuration of an image acquisition unit.

FIG. 3 is an example of the inspection target of a defect inspection device and acquired images.

FIG. 4 is an outline of the inspection operation of a defect inspection device.

FIG. 5A is an example of a deep learning model generation process.

FIG. 5B is another example of the deep learning model generation process.

FIG. 6 is an example of a configuration of a defect inspection system.

FIG. 7 is an example of a timing chart of the deep learning model generation process.

FIG. 8A is an example of an operation screen.

FIG. 8B is an example of the operation screen.

FIG. 8C is an example of the operation screen.

FIG. 8D is an example of the operation screen.

FIG. 9 is an example of the operation screen.

### DESCRIPTION OF EMBODIMENTS

Hereinafter, an embodiment of the present invention will be described in detail with reference to the drawings. In all of the drawings for describing the embodiment, the same members are generally given the same reference numerals, and repeated description will be omitted.

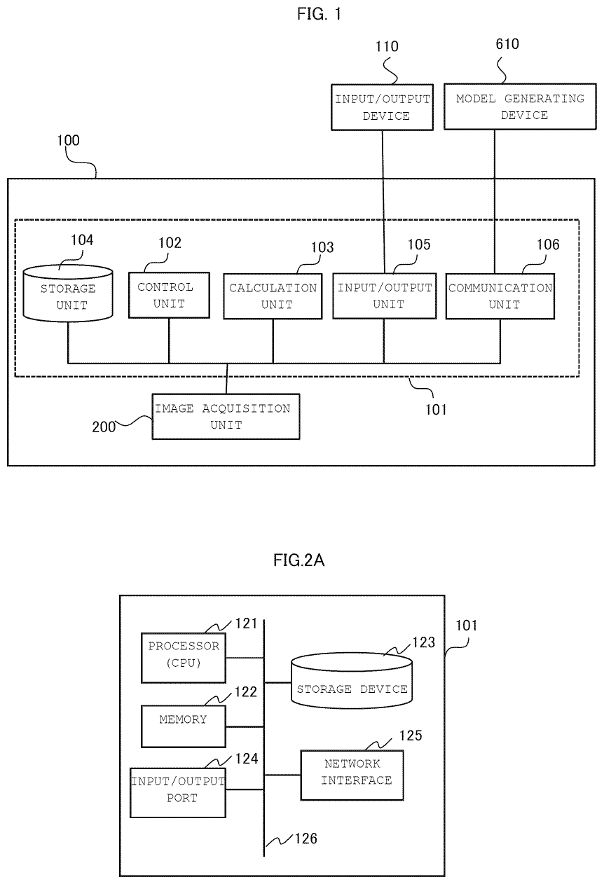

FIG. 1 shows an example of a configuration of a defect inspection device 100 in this example. The defect inspection device of this example is a device that detects defects that are present on the surface of a sample on the basis of a signal obtained by irradiating the sample with electromagnetic waves such as light or a charged particle beam such as an electron beam. Examples of the device include a bright-field inspection device that irradiate a sample with light and detects defects on the basis of reflected light, a dark-field inspection device that irradiates a sample with light and detects defects on the basis of scattered light, and an electron beam inspection device (also including a device referred to as a review SEM) that detects defects on the basis of secondary electrons obtained by irradiating sample with an electron beam. The defect inspection device 100 of this example includes, main functional blocks, an image acquisition unit 200, a control unit 102, a calculation unit 103, a storage unit 104, an input/output unit 105, and a communication unit 106. The input/output unit 105 is connected to an input/output device 110. The input/output device 110 includes input devices such as a keyboard and a pointing device, and a display device such as a display. The communication unit 106 is connected to a model generating device 610. The image acquisition unit 200 acquires inspection image data of a semiconductor wafer. The calculation unit 103 extracts defect candidate images on the basis of a feature value of an image transferred from the image acquisition unit 200, performs a Nuisance removal process by deep learning to be described later, and transmits data on the remaining defect candidates (hereinafter referred to as defect candidate data) to the control unit 102. The defect candidate data includes information such as coordinates on the sample indicating a position where an image is acquired and an evaluation value (DOI-likeness) in addition to, for example, image data. The control unit 102 stores the received defect candidate data in the storage unit 104, transmits, to the input/output unit 105, data that can be used to create inspection conditions and confirm results in the received defect candidate data, and transmits data used to generate a model for Nuisance removal, which will be described later, to the communication unit 106. The input/output unit 105 processes the received defect candidate data into a form that can be visually confirmed by humans, and transmits it to the input/output device 110. The input/output device 110 outputs the received defect candidate data on a screen. The communication unit 106 transmits the defect candidate data to the model generating device 610.

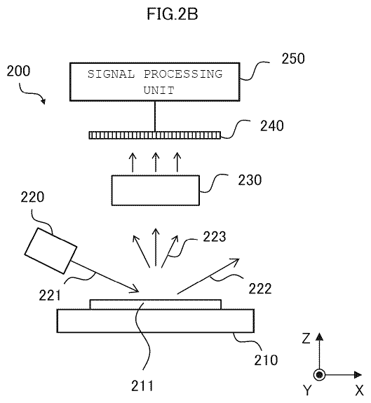

The functional blocks of the control unit 102, the calculation unit 103, the storage unit 104, the input/output unit 105, and the communication unit 106 of the defect inspection device 100 are implemented by an information processing device 101. The information processing device 101 includes a processor (CPU) 121, a memory 122, a storage device 123, an input/output port 124, a network interface 125, and a bus 126 as shown in FIG. 2A. The processor 121 functions as a functional unit (functional block) that provides a predetermined function by executing processing in accordance with a program loaded into the memory 122. The storage device 123 stores data and programs used in the functional units. For the storage device 123, a non-volatile storage medium such as a hard disk drive (HDD) or a solid state drive (SSD) is used. The input/output port 124 is connected to the input/output device 110 and executes signal exchange between the information processing device 101 and the input/output device 110. The network interface 125 enables communication with other information processing devices via a network. The other information processing devices include a model generating device 610. These components of the information processing device 101 are connected to each other via the bus 126 so that they can communicate with each other.

FIG. 2B shows an example of a configuration of the image acquisition unit 200 of the defect inspection device 100. Here, an example of an optical inspection device that detects defects using light is shown. The image acquisition unit 200 includes a stage 210, a lighting optical system 220, a detection optical system 230, an image sensor 240, and a signal processing unit 250. A sample 211 is an object to be inspected, such as a semiconductor wafer. The stage 210 carries the sample 211 and can move in an XY plane, rotate (θ), and move in a Z direction.

The lighting optical system 220 irradiates the sample 211 with light 221. When the light 221 hits the sample 211, reflected light 222 and scattered light 223 are generated from the sample 211.

The detection optical system 230 directs the reflected light 222 or scattered light 223 to an imaging surface of the image sensor 240. The image sensor 240 images the scattered light 223. The detection optical system 230 may include a spatial filter that cuts out light generated from a pattern that is repeated at a certain cycle. The image sensor 240 transmits an imaging signal to the signal processing unit 250.

The signal processing unit 250 processes the imaging signal received from the image sensor 240 and generates an observation image of the surface of the sample 211. The observation image acquired by irradiating the sample 211 with the light 221 from diagonally above is referred to as a dark-field image. The observation image may also be obtained by imaging the reflected light 222 from the sample 211 from above the sample 211. The observation image acquired by this method is referred to as a bright-field image.

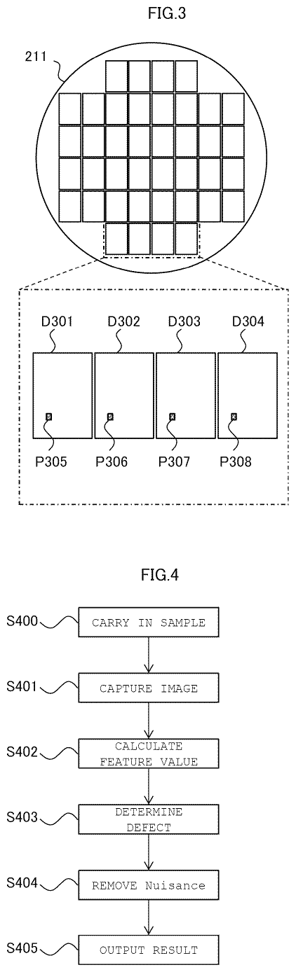

FIG. 3 shows a schematic plan view of the sample 211. When the sample 211 is a patterned semiconductor wafer, a circuit pattern of a semiconductor chip is formed on the surface of the sample 211. Each semiconductor chip before being separated from the semiconductor wafer is referred to as a die. All dies have the same circuit patterns. There is no particular limitation on an inspection method, but here, an image of the entire surface of the semiconductor wafer is captured and divided into images of a predetermined size. Below, these divided images are referred to as observation images. Since dies D301 to D304 in FIG. 3 have the same circuit pattern, observation images of regions P305 to P308 occupying the same coordinates on the dies are the same when there are no defects. On the other hand, for example, when only the observation image of the region P305 among the observation images of the regions P305 to P308 has a high brightness value, there is a possibility that there will be, for example, foreign matter at the position of the region P305. Consequently, the observation image of the region P305 is extracted as a defect candidate image. Here, an example in which a defect candidate image is extracted using a difference in brightness (lightness) of the observation image as a feature value has been described, but the feature value is not limited thereto, and a plurality of feature values can also be used.

FIG. 4 is a diagram showing an outline of an inspection operation of the defect inspection device 100. When the inspection is started, the sample 211 is carried into the defect inspection device 100 (S400). Next, the image acquisition unit 200 captures an observation image (S401). Next, the calculation unit 103 performs, on the acquired observation image, a feature value calculation process for calculating a difference, for example, by comparing lightnesses of observation images of regions occupying the same coordinates on dies (S402), and extracts defect candidates by operations such as comparison with a separately calculated threshold value and a filter process using a feature value (S403). In this example, further, Nuisance is removed from the defect candidates extracted in step S403 to specify defects by using the deep learning model generated by the model generating device 610 (S404), and inspection results are output (S405).

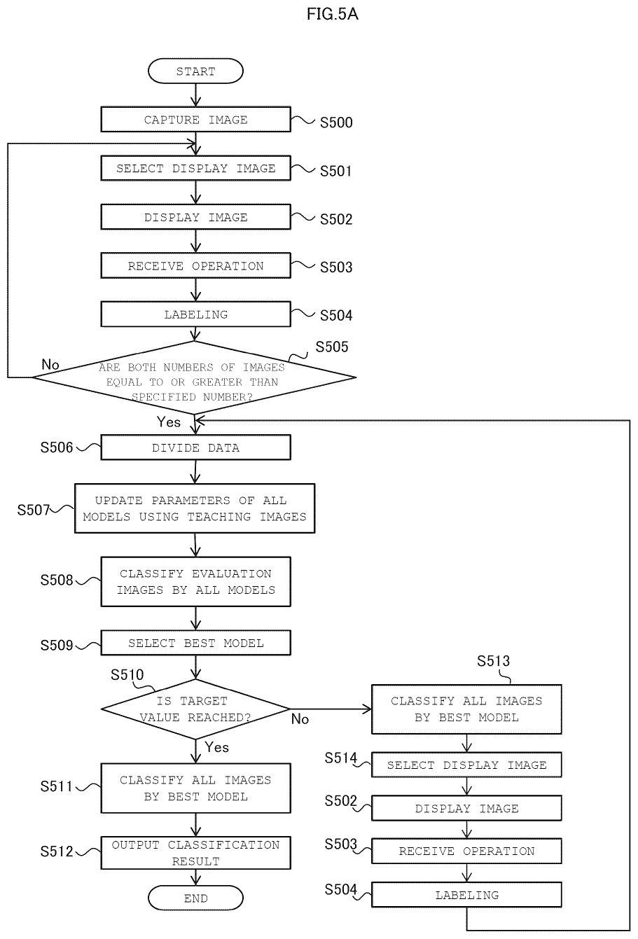

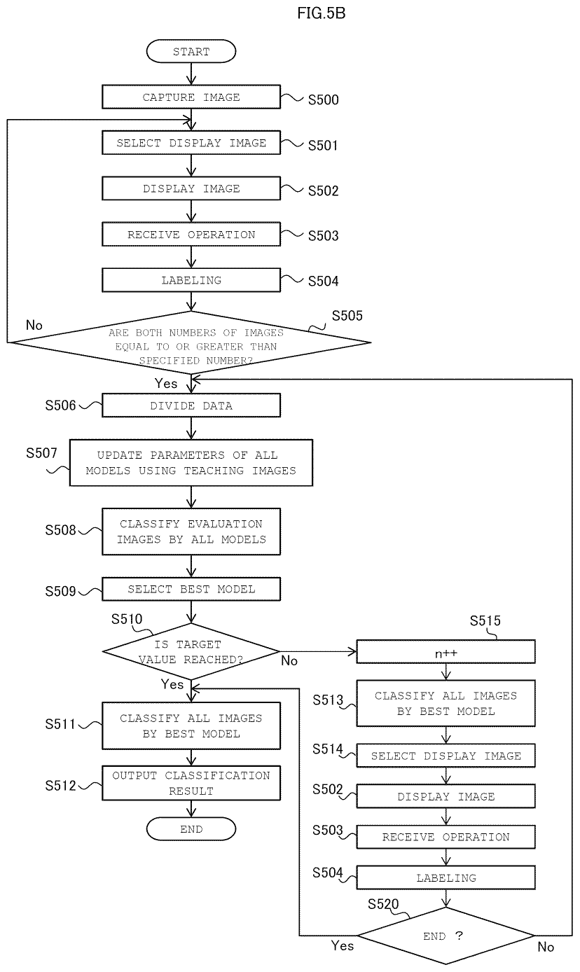

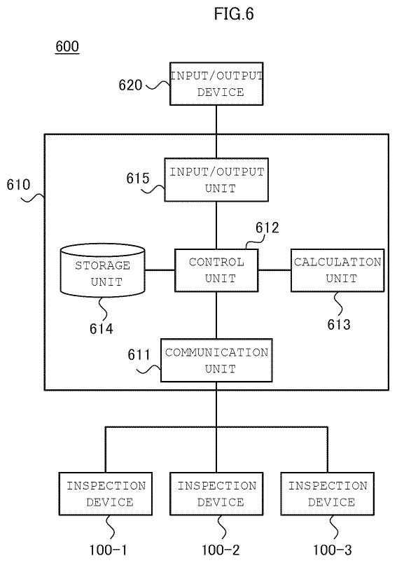

An example of a deep learning model generation process will be described using a flow in FIG. 5A. This process is executed by the model generating device 610. First, the defect inspection device 100 reads the defect candidate image acquired by executing the flow in FIG. 4 (S500). When a plurality of defect inspection devices each acquire defect candidate images, the defect candidate images from the defect inspection devices may be read. As the defect candidate images, defect candidate images extracted by inspection with normal inspection sensitivity may be used, or defect candidate images extracted by inspection with extremely increased inspection sensitivity may be used. In the latter case, the defect candidate images extracted in step S403 will include a large amount of Nuisance, but this example includes a step (S404) of removing Nuisance using the deep learning model, and thus inspection results will not be deteriorated.

Next, approximately 10 images are randomly selected from among the read defect candidate images (S501). Alternatively, in order to efficiently proceed with learning of a model to be described later, the selected defect candidate images may be selected such that image feature values of the images are sparse. For example, when the image feature value is set to be the brightness of the defect candidate image, the defect candidate image is selected such that the defect candidate images thoroughly include high-brightness defect candidate images to low-brightness defect candidate images. The selected defect candidate images are displayed on a GUI of the input/output device 110 (S502), and a user's operation is received (S503). Next, a label of “DOI” or “Nuisance” is assigned to each defect candidate image in response to the user's operation, and classification is performed (S504). It is determined whether the number of images with the label “DOI” and the number of images with the label “Nuisance” are each equal to or greater than a specified number (S505). The specified number is determined to be, for example, 5 or more. When the specified number is not satisfied, the process returns to the selection of a display image (S501). When the specified number is satisfied, the defect candidate images are classified as teaching images and evaluation images, respectively (S506). This division is performed such that the proportion of each classes (images with the label “DOI” and images with the label “Nuisance”) included in the teaching images and the evaluation images is equal.

Next, a deep learning model for classifying DOI and Nuisance is trained. As described above, an optimal network configuration of the deep learning model may vary for each image type. For this reason, a plurality of models are prepared in advance in the model generating device 610. For example, when a convolutional neural network (CNN) is used for determination, a plurality of CNNs with different hyper parameters are prepared. The plurality of CNNs are trained using the teaching images, and the CNN determined with the highest accuracy among them is selected as a model for classifying DOI and Nuisance of the image type. Thereby, it is possible to cope with various image types. Description is given along a flow below.

First, the parameters of the plurality of models prepared in advance are updated (trained) using the teaching images (S507), and the evaluation images are classified using the plurality of models (S508). The models prepared in advance may be models that have been previously trained using other inspection results or may be untrained models, or both of them may be included. For example, the model outputs the probability that an input image will be DOI (hereinafter referred to as a DOI-likeness), and thus a best threshold value making it possible to classify the evaluation images into DOI and Nuisance is also recorded. The DOI-likeness may be determined on the basis of the probability of being Nuisance. Next, the model with the highest performance in classifying the evaluation images is selected as a best model (S509). For example, the accuracy of the model can be evaluated using an area under curve (AUC) of a ROC curve as an index of the classification accuracy of the model. Next, it is determined whether the classification accuracy (for example, AUC) of the selected best model reaches a preset target value (S510). The target value may be changed by the user.

When the target value is not reached, all images that are not labeled by the best model, that is, images that are not classified as “DOI” or “Nuisance”, are classified (S513), and several images with the highest DOI-likeness (images with a DOI-likeness that is the maximum value or close to the maximum value), several images with a DOI-likeness closest to the threshold value recorded in step S508 (images with a DOI-likeness that is the threshold value or close to the threshold value), and several images with the lowest DOI-likeness (images with a DOI-likeness that is the minimum value or close to the minimum value) are selected (S514). The selection method is not limited thereto, and several images may be selected such that they are lined up at equal intervals when they are arranged in order of DOI-likenesses determined by the best model. Images are selected on the basis of some criteria using a DOI-likeness. Alternatively, images may be selected on the basis of image feature values. In either case, images are selected to cover the spread of DOI-likeness or image feature values in all images and to avoid arbitrary bias. In deep learning, inference results for images of a type that has not been learned are ambiguous. As described above, it is possible to efficiently improve the accuracy of the model by repeating a process of selecting images to be used as teaching images to cover the entire variability of the image type and performing training using the created teaching images. After the selection of the display image (S514) is completed, the image is displayed (S502), an operation is received (S503), labels are assigned (S504), and then the process returns to the division of image data (S506).

On the other hand, when the classification accuracy of the best model reaches the preset target value, the best model is determined as a deep learning model for classifying the image types of the defect candidate images into DOI and Nuisance. Furthermore, all images that are not labeled by the best model may be classified (S511). An image of which the DOI-likeness determined by the best model exceeds the threshold value recorded in step S508 may be output as DOI, and which defect candidate image was determined to be DOI may be stored in the storage unit (S512). The classification of DOI and Nuisance is performed by comparing the probability of being DOI (DOI-likeness) output by the model with the threshold value, and the threshold value used is the value recorded in step S508, but the user may adjust the threshold value and use it.

Another example of the deep learning model generation process will be described using a flow in FIG. 5B. The same parts as in the flow in FIG. 5A will not be described. A difference from the flow in FIG. 5A is that the accuracy determination to be performed by the user (S520) is included. When the user executes an operation of transmitting the end when viewing the image during the labeling (S504) and feeling that the classification accuracy is sufficiently high even when it is determined that the classification performance of the evaluation image by the best model does not reach the target value, the process can proceed to the process of classifying all images by the best model (S511) and the process of outputting an analysis result (S512). In step S520, the classification accuracy of the best model may be displayed on an operation screen, and the user may view the numerical value and make a determination.

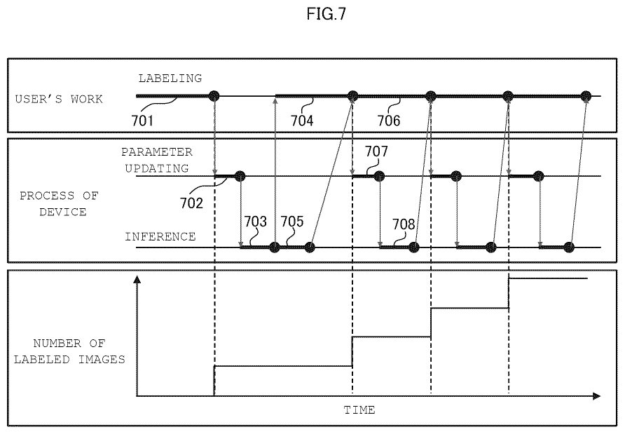

FIG. 6 shows an example of a system configuration of the defect inspection system 600 of this example. The defect inspection system 600 includes one or more inspection devices 100-1 to 100-3, the model generating device 610, and an input/output device 620. The input/output device 620 includes an input device such as a keyboard or a pointing device, and a display device such as a display. Functional blocks of the model generating device 610 such as a communication unit 611, a control unit 612, a calculation unit 613, a storage unit 614, and an input/output unit 615 are implemented by an information processing device. A hardware structure of the information processing device is the same as that of the information processing device 101 shown in FIG. 2A, and thus repeated description will be omitted.

In generating the model, defect candidate images are acquired using the inspection devices 100-1 to 100-3. The number of inspection devices used at this time may be one, or some or all of inspection devices in an inspection device group may be used. In addition, samples inspected by the inspection devices may be, for example, the same semiconductor wafer or different semiconductor wafers on which dies with the same circuit pattern are formed. The inspection devices 100-1 to 100-3 transmit information on the defect candidates generated by themselves to the communication unit 611 of the model generating device 610 via a network. The model generating device 610 generates a deep learning model that is used in step S404 for the defect inspection by the inspection device 100 in accordance with the flow in FIG. 5A or FIG. 5B by using the transmitted defect candidate images.

The calculation unit 613 trains one or more untrained models or pre-trained models stored in the storage unit 614 by using the received defect candidate images. As described above, a plurality of deep learning models with different hyper parameters are stored in advance in the storage unit 614. At this time, in order to acquire a labeled image necessary for model training, defect candidate images selected as label assignment targets from among unlabeled images are transmitted to the input/output unit 615. The input/output unit 615 displays the received defect candidate images on the display device of the input/output device 620 (S502). The input device of the input/output device 620 receives the user's operation and transmits a signal for label assignment to the input/output unit 615. The input/output unit 615 assigns a label to the defect candidate image using the received signal and transmits it to the calculation unit 613 and the storage unit 614. The calculation unit 613 updates the parameters of the deep learning model by using the received labeled images (S507). Each time the parameter update is completed, the calculation unit 613 may evaluate the model using the labeled images stored in the storage unit 614 to confirm the accuracy. When the user performs an operation to complete the learning (Yes in S510 or S520), the control unit 612 transmits the best model at that time to each of the inspection devices 100-1 to 100-3 via the communication unit 611.

The timing at which the inspection devices 100-1 to 100-3 update the model used in step S404 is arbitrary. For example, the updating may be performed using a result of the accuracy evaluation, which is performed by the calculation unit 613 using the labeled images stored in the storage unit 614, as a trigger. The inspection devices 100-1 to 100-3 use the received trained model to remove Nuisance from results of inspections to be performed subsequently and specify defects. The received deep learning model may be used repeatedly.

In the deep learning model generation process shown in FIG. 5A or FIG. 5B, the user's work (labeling (S504)), the process of the model generating device 610, and the transition of the number of labeled images accompanying these processes are shown in FIG. 7. As described in the flow of the deep learning model generation process, the model generating device 610 updates the parameters of the plurality of deep learning models by using labeled images (teaching images) obtained by the user's labeling work. Since the updating of the parameters (S507) and the next inference process (S513) of a DOI-likeness for all unlabeled images required to select a teaching image takes time, when the respective operations are performed in series, there is a concern of a waiting time occurring from when the user's work (S504) ends to when the model generating device 610 performs these processes and the next labeling target image is displayed (S502). In order to curb the generation of such a waiting time, the user's work and the process of the model generating device may be executed in parallel, as shown in the timing chart in FIG. 7.

After the user's first labeling work 701 is completed and a parameter updating process 702 and an inference process 703 of the model generating device 610 are completed, an inference process 705 for selecting the next labeling target image is executed in parallel with the user's second labeling work 704. Since the inference processes 703 and 705 are inferences using the same model, the same inference results are obtained. However, in the inference process 705, an image that is a target for the second labeling work 704 is not subjected to inference, and thus an image that has not yet been subjected to a labeling process can be selected as a labeling target image by the inference process 705. The next labeling target image selected by the inference process 705 is displayed as soon as the user's second labeling work 704 is completed, and the process proceeds to third labeling work 706. In addition, at the same time when the third labeling work 706 is started, the next parameter updating process 707 and inference process 708 are started in parallel.

In this manner, in the repetition of labeling and learning/inference, it is possible to perform the user's labeling work and the learning/inference process of the device in parallel by performing the first inference twice. Thereby, it is possible to hide the time required for the process of the model generating device 610 and improve the processing efficiency. Instead of performing the first inference twice, target images for two sets of labeling work may be selected for the first inference.

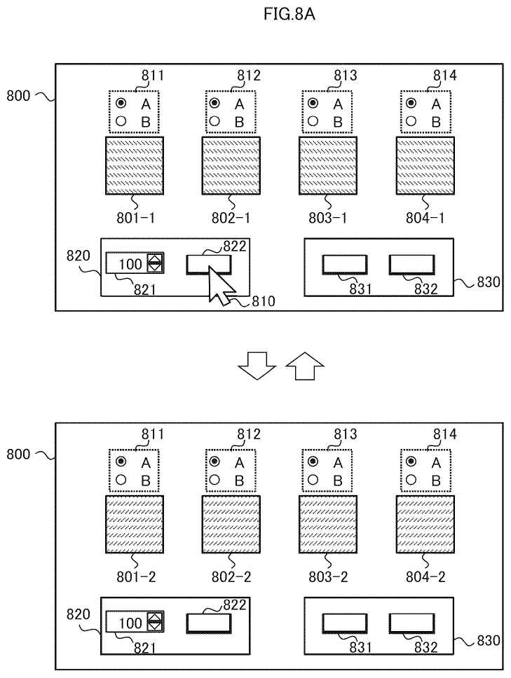

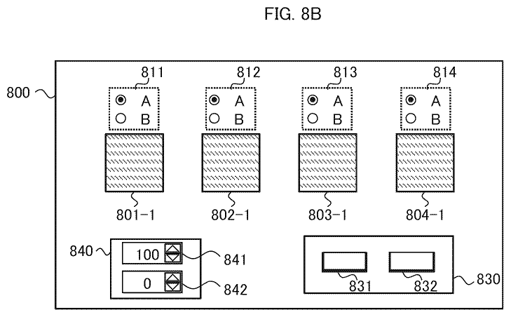

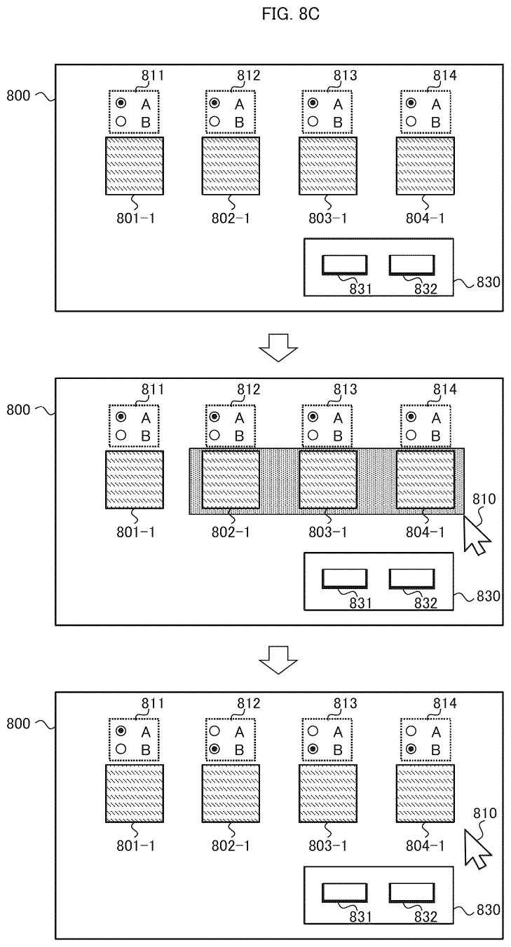

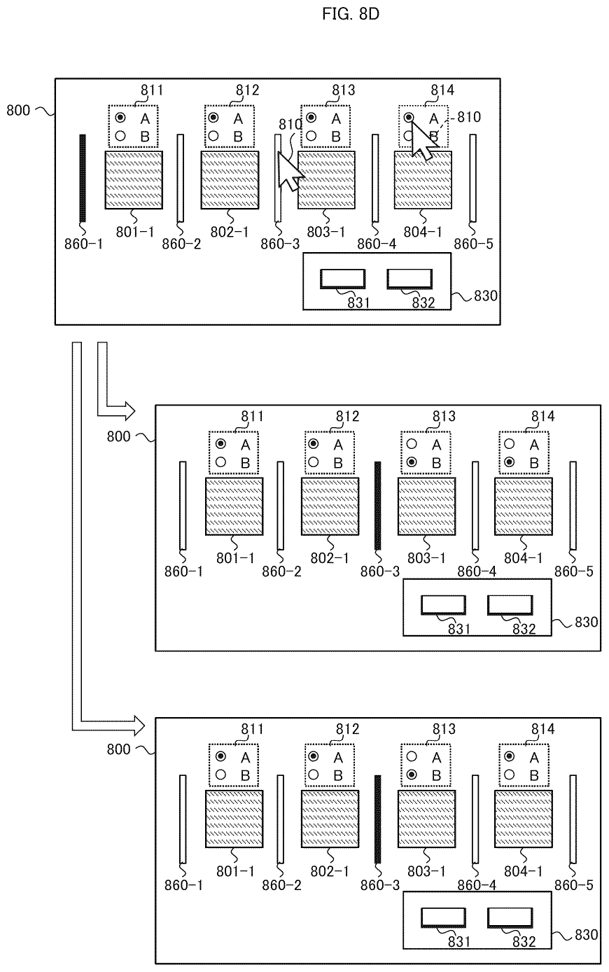

FIGS. 8A to 8D show an example of an operation screen in this example. By using a GUI with high operability for the operation screen, the time required for teaching can be reduced. At least several labeling target images 801 to 804, label selection buttons 811 to 814 provided corresponding to the labeling target images, and an operation completion button group 830 are displayed in a pop-up window 800 which is an operation screen. An image switching control button group 820 shown in FIG. 8A may be displayed in the pop-up window 800. Alternatively, an image display method adjustment button group 840 shown in FIG. 8B may be displayed. Alternatively, division boundary selection buttons 860-1 to 860-5 shown in FIG. 8D may be displayed. Operations for this operation screen will be described below with reference to FIGS. 8A to 8D.

The labeling target images selected in steps S501 and S514 are displayed in descending order of a DOI-likeness on the operation screen. The number of images displayed is approximately ten to several tens of images. When all of the images cannot be displayed at once in the pop-up window 800, a scroll operation is received so that the labeling target images to be displayed can be switched. The label selection buttons 811 to 814 respectively corresponding to the displayed labeling target images 801 to 804 are placed near the labeling target images, and a label to be assigned to each labeling target image can be selected by clicking with a mouse pointer 810. The label selection button can be a radio button as shown in FIG. 8 (here, DOI is written as “A”, and Nuisance is written as “B”), the initial state may be set to DOI or Nuisance, an image to which the opposite label is to be assigned may be clicked with the mouse pointer 810, or a check box may be set so that only DOI or Nuisance can be clicked. As shown in FIG. 8C, a rectangle may be selected by dragging the mouse pointer 810, and the label of an image within the rectangular region may be inverted. Alternatively, as shown in FIG. 8D, by clicking any of the division boundary selection buttons 860-1 to 860-5 with the mouse pointer 810, the labels of all images displayed to the left or right of the boundary may be inverted. At this time, when individual label selection buttons 811 to 814 are clicked before clicking the division boundary selection buttons 860-1 to 860-5, a process in which the label of the image is not inverted may be performed.

When an operation completion button 831 placed in the operation completion button group 830 is clicked with the mouse pointer 810, a label designated by the user is assigned to the displayed labeling target images 801 to 804, the images are stored, and the next labeling target image is displayed. In addition, a teaching completion button 832 may be placed in the operation completion button group 830. Clicking this button with the mouse pointer 810 may end the labeling process and proceed to the next process.

As shown in FIG. 8A, defect candidate images 801-1 to 804-1 to be labeled and corresponding reference die images 801-2 to 804-2 may be displayed alternately. The defect candidate images are grouped on the basis of coordinate information on the die, and the reference die images are selected from observation images (see FIG. 3) of regions occupying the same coordinates on the dies. Image switching may be stopped by clicking an image switching on/off button 822 placed in the image switching control button group 820 shown in FIG. 8A with the mouse pointer 810. In addition, an image to be displayed may be switched at every time which is input to a switching speed adjustment box 821 placed in the image switching control button group 820 or which is set using a button.

In addition, when the lightnesses of the labeling target images 801 to 804 displayed in the pop-up window 800 can be adjusted, the user can easily make a determination. The image quality of the labeling target images can be adjusted by the image display method adjustment button group 840 shown in FIG. 8B. For example, in the image display method adjustment button group 840, a box 841 for setting the maximum lightness and a box 842 for setting the minimum lightness are placed. The lightness may be adjusted by setting pixels with a tone equal to or higher than a tone, which is set as the maximum lightness, as white pixels, setting pixels with a tone equal to or lower than a tone, which is set as the minimum lightness, as black pixels, and evenly allocating pixel values with tones between the maximum lightness and the minimum lightness to the maximum tone to the minimum tone of the display of the input/output device 620.

In the examples of FIGS. 8A to 8D, the labeling target images are displayed side by side in the horizontal direction, but they may be displayed side by side in the vertical direction.

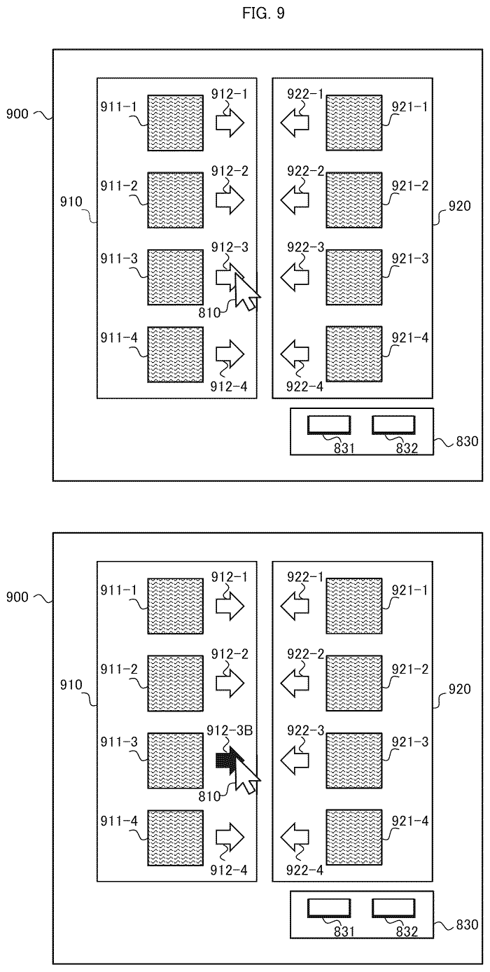

FIG. 9 shows another configuration example of the operation screen. In a pop-up window 900, a group of labeling target images 911-1 to 911-4 that are inferred to have a high DOI-likeness is displayed in a left region 910, and a group of labeling target images 921-1 to 921-4 that are inferred to have a low DOI-likeness is displayed in a right region 920. Images that are erroneously classified can be selected and corrected by clicking arrows 912-1 to 912-4 or arrows 922-1 to 922-4 that are provided corresponding to the images with the mouse pointer 810.

The present invention is not limited to the above example, and various modification examples are included. For example, the above-described example has been described in detail in order to facilitate the understanding of the present invention, and is not necessarily limited to having all of the configurations described.

For example, in the example, an inspection device that detects defects on a semiconductor wafer on which a pattern is formed has been described as an example, but it is also possible to remove Nuisance in an inspection device that detects defects on a semiconductor wafer on which no pattern is formed (hereinafter referred to as a surface inspection device). The surface inspection device is a device that detects defects such as foreign matter and scratches on the surface by irradiating the surface of a sample such as a wafer with light such as laser light. When inspecting the surface of the wafer using the surface inspection device, the sample is fixed onto a rotating stage or a stage that moves in the XYZ directions by using, for example, a vacuum chuck or a holding device, and the surface of the sample is irradiated with light while moving the sample to observe reflected light and scattered light generated at that time. Foreign matter, scratches, and the like on the surface of the sample are detected by detecting a difference between when the surface of the sample is as expected (defect-free) and when there are foreign matter or scratches. The surface inspection device detects defects by comparing signal waveforms obtained, and can remove Nuisance using a trained model. For classification for training a model, data obtained by converting waveform information into an image may be used, the waveform information may be used as it is, coordinate information on the sample may be used, or a combination of these pieces of information may be used.

Further, in the example, description has been given of an example in which a model for removing Nuisance is generated by a model generating device connected to a defect inspection device, but the model may be generated by installing software for model generation in an information processing device of the defect inspection device.

### REFERENCE SIGNS LIST

100: defect inspection device
101: information processing device
102: control unit
103: calculation unit
104: storage unit
105: input/output unit
106: communication unit
110: input/output device
121: processor (CPU)
122: memory
123: storage device
124: input/output port
125: network interface
126: bus
200: image acquisition unit
210: stage
211: sample
220: lighting optical system
221: light
222: reflected light
223: scattered light
230: detection optical system
240: image sensor
250: signal processing unit
600: defect inspection system
610: model generating device
611: communication unit
612: control unit
613: calculation unit
614: storage unit
615: input/output unit
620: input/output device
701, 704, 706: labeling work
702, 707: parameter updating process
703, 705, 708: inference process
800, 900: pop-up window
801, 802, 803, 804, 911, 921: labeling target image
810: mouse pointer
811, 812, 813, 814: label selection button
820: image switching control button group
821: switching speed adjustment box
822: image switching on/off button
830: operation completion button group
831: operation completion button
832: teaching completion button
840: image display method adjustment button group
841, 842: box
832: teaching completion button
860: division boundary selection button
910: left region
920: right region
912, 922: arrow

1. A model generating method for generating a deep learning model for classifying defect candidate images into DOI and Nuisance, the model generating method comprising:
a first step of preparing a plurality of deep learning models with different hyper parameters in advance and reading defect candidate images to be used for training the deep learning models;
a second step of labeling some of the defect candidate images to create teaching images and evaluation images;
a third step of evaluating classification accuracy using the evaluation images after updating parameters for each of the plurality of deep learning models using the teaching images, and selecting a best model with the highest classification accuracy from among the plurality of deep learning models; and
a fourth step of classifying the defect candidate images that have not been labeled using the best model, and selecting some of the defect candidate images to be labeled based on a DOI-likeness according to the best model,
wherein the second step and the third step are executed again after executing the fourth step.

2. The model generating method according to claim 1, wherein,
when the best model selected in the third step does not satisfy a desired classification accuracy, the fourth step is executed following the third step, and
when the best model selected in the third step satisfies the desired classification accuracy, the best model is used as a deep learning model for classifying image types of the defect candidate images into DOI and Nuisance.

3. The model generating method according to claim 1, wherein,
the best model records a threshold value of the DOI-likeness for classifying the evaluation images into DOI and Nuisance in the third step, and
the defect candidate images to be labeled are selected in the fourth step so that images of which the DOI-likeness evaluated by the best model is the threshold value or close to the threshold value, images of which the DOI-likeness evaluated by the best model is a maximum value or close to the maximum value, and images of which the DOI-likeness evaluated by the best model is a minimum value or close to the minimum value are included.

4. The model generating method according to claim 1, wherein, when the second to fourth steps are repeatedly executed, the third step and the second step for some of the defect candidate images selected in the fourth step are executed in parallel.

5. The model generating method according to claim 1, wherein
in the second step after the fourth step is executed, a window for allowing a user to select whether some of the defect candidate images are DOI or Nuisance is displayed on a display device, and
the defect candidate images displayed in the window are displayed in order of DOI-likenesses evaluated by the best model.

6. The model generating method according to claim 5, wherein the window is provided with a button for selecting whether the defect candidate images are DOI or Nuisance corresponding to the defect candidate images displayed in the window.

7. The model generating method according to claim 6, wherein the window is provided with division boundary selection buttons between the defect candidate images displayed in the window, and any of the division boundary selection buttons is designated to select one defect candidate image divided by the division boundary selection button as DOI and select the other defect candidate image as Nuisance.

8. The model generating method according to claim 1, wherein
in the second step after the fourth step is executed, a window for allowing a user to specify whether some of the defect candidate images are DOI or Nuisance is displayed on a display device, and
the defect candidate images displayed in the window are displayed to be divided into a group evaluated to have a high DOI-likeness by the best model and a group evaluated to have a low DOI-likeness.

9. A defect inspection system comprising:
a defect inspection device; and
a model generating device that is connected to the defect inspection device and configured to generate a deep learning model for classifying defect candidate images acquired by the defect inspection device into DOI and Nuisance, wherein
the defect inspection device includes image acquisition unit that acquires an observation image, and an information processing device that calculates a feature value of the observation image to extract defect candidate images and specifies, as defects, defect candidate images classified as DOI by using the deep learning model from among the extracted defect candidate images,
the model generating device includes a storage unit that stores in advance a plurality of deep learning models with different hyper parameters, and a calculation unit that executes first to fourth steps,
the first step includes reading defect candidate images to be used for training the deep learning model,
the second step includes labeling some of the defect candidate images to create teaching images and evaluation images,
the third step includes evaluating classification accuracy using the evaluation images after updating parameters for each of the plurality of deep learning models using the teaching images, and selecting a best model with the highest classification accuracy from among the plurality of deep learning models,
the fourth step includes classifying the defect candidate images that have not been labeled by the best model, and selecting some of the defect candidate images to be labeled based on a DOI-likeness according to the best model, and
the second step and the third step are executed again after executing the fourth step.

10. The defect inspection system according to claim 9, wherein
when the best model selected in the third step does not satisfy a desired classification accuracy, the calculation unit executes the fourth step following the third step, and
when the best model selected in the third step satisfies the desired classification accuracy, the best model is determined as a deep learning model to be used in the defect inspection device.

11. The defect inspection system according to claim 9, wherein the defect candidate images include an image of a background pattern and an image of a defect candidate.

12. The defect inspection system according to claim 9, wherein the image acquisition unit acquires the observation image based on a signal obtained by irradiating an inspection target sample with an electromagnetic wave or a charged particle beam.
